(19) United States
(12) Patent Application Publication
(10) Pub. No.: US 2011/0277832 A1
(43) Pub. Date: Nov. 17, 2011

(54) METHOD FOR PRODUCTION OF TITANIUM DIOXIDE COMPOSITE AND PHOTOELECTRIC CONVERSION DEVICE INCORPORATED WITH THE SAME

(75) Inventors: Keisuke Shimizu, Kanagawa (JP); Osamu Enoki, Kanagawa (JP); Yuri Nakayama, Kanagawa (JP); Kazuaki Fukushima, Kanagawa (JP)

(73) Assignee: Sony Corporation, Tokyo (JP)

(21) Appl. No.: 13/099,734

(22) Filed: May 3, 2011

(30) Foreign Application Priority Data
May 13, 2010 (JP) 2010-111242

(51) Int. Cl. H01L 31/0224; H01L 51/44; H01L 21/36; B32B 5/16

(52) U.S. Cl. 136/256; 428/372; 438/104; 257/E21.461

(57) ABSTRACT

Disclosed herein is a method for production of a titanium dioxide composite, the method including a step of preparing titanium dioxide nanowires, a step of dipping the titanium dioxide nanowires in a solution containing titanium oxysulfate and urea, thereby forming titanium dioxide fine particles on the surface of the titanium dioxide nanowires, and a step of recovering the titanium dioxide nanowires having the titanium dioxide fine particles formed on the surface thereof.

### BACKGROUND OF THE INVENTION

1. Field of the Invention

The present invention relates to a titanium dioxide composite and, more particularly, to a titanium dioxide composite applicable to a semiconductor layer of a photoelectric conversion device, a method for production thereof, and a photoelectric conversion device incorporated therewith.

2. Description of the Related Art

Photovoltaic power generation is becoming more important in response to the recent increasing public concern about environmental protection. Among possible means to achieve it is a dye-sensitized solar cell (DSSC), which is composed of a working electrode and a counter electrode, with an oxidation-reduction electrolyte layer interposed between them. The working electrode is composed of a transparent conductive layer and an oxide semiconductor layer which are formed on a transparent substrate. The oxide semiconductor layer supports a sensitizing dye. The working electrode is also called photoelectrode or window electrode. The dye-sensitized solar cell functions as a battery as the sunlight excites electrons in the dye and the excited electrons enter the oxide semiconductor layer and then the transparent conductive layer so that an electric current flows to the counter electrode through the external circuit connected to loads.

The dye-sensitized solar cell has an advantage over silicon solar cells in being less limited in resources for its raw materials, requiring no vacuum equipment, and being capable of production at low cost by printing or flow system. For this reason, it is under extensive development.

The oxide semiconductor layer as one constituent of the dye-sensitized solar cell is usually formed from titanium dioxide, and much has been studied about titanium dioxide so that it increases in dye adsorbing capacity and improves in photoelectric conversion efficiency. In this connection, attempts are being made to develop titanium dioxide having a large specific surface area or develop a titanium dioxide nanowire composite.

Examples of such attempts include synthesis of titanium dioxide film having a large specific surface area in a solution containing urea and titanium oxysulfate (see S. Yamabi, H. Imai, “Synthesis of rutile and anatase films with high surface areas in aqueous solutions containing urea,” Thin Solid Films 434 (2003) 86-93 (2. Experimental), hereinafter referred to as Non-Patent Document 1) and methods for production of a titanium dioxide nanowire composite (see Japanese Patent Laid-Open No. 2007-70136 (Paragraphs 0010 to 0012, and FIGS. 3 and 4) and Japanese Patent Laid-Open No. 2006-182575 (Paragraphs 0010 to 0014), hereinafter referred to as Patent Documents 1 and 2 and B. Liu et al., “Oriented single crystalline titanium dioxide nanowires,” Nature Nanotechnology 19, 505604 (2008) (2. Experimental details, 3. Results and discussion), hereinafter referred to as Non-Patent Document 2).

The titanium dioxide nanowire composite is expected to find use as the oxide semiconductor layer because of its large specific surface area (which leads to a large dye adsorbing capacity) and its good electron conductivity in the lengthwise direction of the nanowire (see Patent Document 1 and Japanese Patent Laid-Open No. 2008-277019 (Paragraphs 0012 to 0016 and 0046 to 0066), hereinafter referred to as Patent Document 3).

Patent Document 3, which is entitled “Photoelectric cell and coating material to form porous semiconductor film for said photoelectric cell,” mentions as follows. The porous metal oxide semiconductor film is formed from titanium dioxide particles, each particle including a base particle of titanium dioxide and a layer of titanium dioxide fine particles that covers the surface of the base particle. The titanium dioxide base particles may be titanium dioxide in spherical, fibrous, or tubular form. They may be used alone or in combination with one another. Titanium dioxide in fibrous or tubular form should have an average diameter of 5 to 40 nm (preferably 8 to 30 nm) and an average length of 25 to 1000 μm (preferably 50 to 600 μm).

### SUMMARY OF THE INVENTION

Titanium dioxide to form the semiconductor layer of the photoelectric conversion device may be one in the form of fine particles which has a large specific surface area. It adsorbs a large amount of dye on its surface and hence it provides a large reaction area. However, it causes electrons generated by reaction to be largely lost during their migration to the electrode because there are so many interfaces among particles.

By contrast, titanium dioxide to form the semiconductor layer of the dye-sensitized solar cell may be rod-shaped one (such as nanowire). It permits electrons generated by reaction to effectively migrate to the electrode because there are less interfaces among particles. However, it is limited in the amount of dye to be adsorbed because of its small specific surface area, which leads to an insufficient reaction area.

The foregoing has aroused a need for a semiconductor layer which has a low resistance and a large specific surface area so that the dye-sensitized solar cell has an improved photoelectric conversion efficiency.

The present invention was completed to address the above-mentioned problems. It is desirable to provide a titanium dioxide composite to form the semiconductor layer of the photoelectric conversion device, a method for production thereof, and a photoelectric conversion device incorporated therewith.

A gist of the present invention resides in a method for production of a titanium dioxide composite, the method including the steps of preparing titanium dioxide nanowires, dipping the titanium dioxide nanowires in a solution containing titanium oxysulfate and urea, thereby forming titanium dioxide fine particles on the surface of the titanium dioxide nanowires, and recovering the titanium dioxide nanowires having the titanium dioxide fine particles formed on the surface thereof.

Another gist of the present invention resides in a titanium dioxide composite which is composed of titanium dioxide nanowires and titanium dioxide fine particles formed on the surface thereof, the titanium dioxide nanowires having a diameter no smaller than 50 nm and no larger than 110 nm.

Another gist of the present invention resides in a photoelectric conversion device which is composed of a working electrode provided with a semiconductor layer (e.g., the semiconductor layer 3 defined in the embodiment given later) which is formed from the titanium dioxide composite (e.g., the surface-modified single-crystal titanium dioxide nanowires 8 defined in the embodiment given later), a counter electrode arranged opposite to the working electrode, and an electrolyte layer interposed between the working electrode and the counter electrode, with the titanium dioxide composite having a dye (e.g., the dye 7 defined in the embodiment given later) supported on the surface of the titanium dioxide nanowires and the titanium dioxide fine particles.

The method according to an embodiment of the present invention includes the steps of preparing titanium dioxide nanowires, dipping the titanium dioxide nanowires in a solution containing titanium oxysulfate and urea, thereby forming titanium dioxide fine particles on the surface of the titanium dioxide nanowires, and recovering the titanium dioxide nanowires having the titanium dioxide fine particles formed on the surface thereof. The titanium dioxide composite produced by the foregoing method is made into a semiconductor layer having a large specific surface area. The resulting semiconductor layer is incorporated into a photoelectric conversion device for its improvement in photoelectric conversion efficiency.

The present invention provides a titanium dioxide composite which is composed of titanium dioxide nanowires and titanium dioxide fine particles formed on the surface thereof, the titanium dioxide nanowires having a diameter no smaller than 50 nm and no larger than 110 nm. The titanium dioxide composite is made into a semiconductor layer having a large specific surface area. The resulting semiconductor layer is incorporated into a photoelectric conversion device for its improvement in photoelectric conversion efficiency.

The present invention provides a photoelectric conversion device which is composed of a working electrode provided with a semiconductor layer which is formed from the titanium dioxide composite, a counter electrode arranged opposite to the working electrode, and an electrolyte layer interposed between the working electrode and the counter electrode, with the titanium dioxide composite having a dye supported on the surface of the titanium dioxide nanowires and the titanium dioxide fine particles. The photoelectric conversion device, therefore, has an improved photoelectric conversion efficiency.

### BRIEF DESCRIPTION OF THE DRAWINGS

FIGS. 1A to 1C are diagrams illustrating the method for production of the titanium dioxide composite and the structure of the dye-sensitized solar cell incorporated with the titanium dioxide composite, both pertaining to an embodiment of the present invention;

FIG. 2 is a diagram illustrating an X-ray diffraction pattern of the titanium dioxide nanowires pertaining to an embodiment of the present invention;

FIG. 3 is a diagram illustrating a micrograph, taken by a scanning electron microscope (SEM), of the titanium dioxide nanowires pertaining to an embodiment of the present invention;

FIG. 4 is a diagram illustrating a micrograph, taken by a scanning electron microscope (SEM), of the titanium dioxide nanowires pertaining to an embodiment of the present invention;

FIG. 5 is a diagram illustrating a micrograph, taken by a scanning electron microscope (SEM), of the titanium dioxide nanowires, which have undergone the surface modifying treatment for 90 minutes, pertaining to an embodiment of the present invention;

FIG. 6 is a diagram illustrating a micrograph, taken by a scanning electron microscope (SEM), of the titanium dioxide nanowires, which have undergone the surface modifying treatment for 180 minutes, pertaining to an embodiment of the present invention;

FIGS. 7A and 7B are schematic perspective views showing the structure of the titanium dioxide nanowires which have undergone the surface modifying treatment, pertaining to an embodiment of the present invention;

FIG. 8 is a diagram illustrating the characteristic properties of the dye-sensitized solar cell incorporated with the semiconductor layer (electrode) which has undergone the baking treatment at 150° C., pertaining to an embodiment of the present invention;

FIG. 9 is a diagram illustrating the characteristic properties of the dye-sensitized solar cell incorporated with the semiconductor layer (electrode) which has undergone the baking treatment at 510° C., pertaining to an embodiment of the present invention;

FIG. 10 is a diagram illustrating the current-voltage characteristics of the dye-sensitized solar cell incorporated with the semiconductor layer (electrode) which has undergone the baking treatment at 150° C., pertaining to an embodiment of the present invention;

FIG. 11 is a diagram illustrating the current-voltage characteristics of the dye-sensitized solar cell incorporated with the semiconductor layer (electrode) which has undergone the baking treatment at 510° C., pertaining to an embodiment of the present invention; and

FIGS. 12A and 12B are diagrams illustrating how the solar cell varies in photoelectric conversion efficiency and cell resistance depending on the duration of the surface treatment of the single-crystal titanium dioxide nanowires and the temperature of the baking treatment for the semiconductor layer, pertaining to an embodiment of the present invention.

### DETAILED DESCRIPTION OF THE PREFERRED EMBODIMENTS

The present invention specifies that the method for production of the titanium dioxide composite should preferably employ the titanium dioxide nanowires which have a diameter no smaller than 50 nm and no larger than 110 nm. The thus specified method provides a titanium dioxide composite having a large specific surface area.

Moreover, the present invention specifies that the method for production of the titanium dioxide composite should preferably employ the titanium dioxide fine particles which have a diameter no smaller than 5 nm and no larger than 150 nm. The thus specified method provides a titanium dioxide composite having a large specific surface area.

In addition, the present invention specifies that the method for production of the titanium dioxide composite should preferably employ the titanium dioxide nanowires which are single-crystal nanowires of anatase type. The thus specified method provides a titanium dioxide composite which is superior in adsorption performance and photoelectric conversion efficiency to amorphous titanium dioxide and titanium dioxide of rutile type or brookite type.

Also, the present invention specifies that the method for production of the titanium dioxide composite should preferably employ the titanium dioxide fine particles of anatase type. The thus specified method provides a titanium dioxide composite which is superior in adsorption performance and photoelectric conversion efficiency to amorphous titanium dioxide and titanium dioxide of rutile type or brookite type.

The present invention specifies that the titanium dioxide composite should preferably contain the titanium dioxide fine particles having a diameter no smaller than 5 nm and no larger than 150 nm. The thus specified titanium dioxide composite has a large surface area.

The photoelectric conversion device according to the present invention works in such a way that the sensitizing dye supported on the semiconductor layer absorbs light to excite its electrons and the excited electrons migrate to the external circuit through the semiconductor layer. It is embodied by the dye-sensitized solar cell, which is described below with reference to the accompanying drawings. The embodiment is not intended to restrict the scope of the present invention so long as it is configured to produce the effects mentioned above. Incidentally, the accompanying drawings depict the structure merely for easy understanding and hence their dimensions are not scaled exactly.

The embodiment of the present invention will be described below in more detail with reference to the drawings.

### EMBODIMENT

The titanium dioxide composite according to an embodiment of the present invention is composed of surface-modified single-crystal titanium dioxide nanowires. In other words, it is composed of single-crystal titanium dioxide nanowires of anatase type and titanium dioxide fine particles (fine crystals) of anatase type which are formed on the surface thereof. It has a large surface area. The term “reaction for surface modifying treatment” used hereunder denotes the reaction to cover the surface of the single-crystal titanium dioxide nanowires with the titanium dioxide fine particles (fine crystals), thereby giving the surface-modified single-crystal titanium dioxide nanowires.

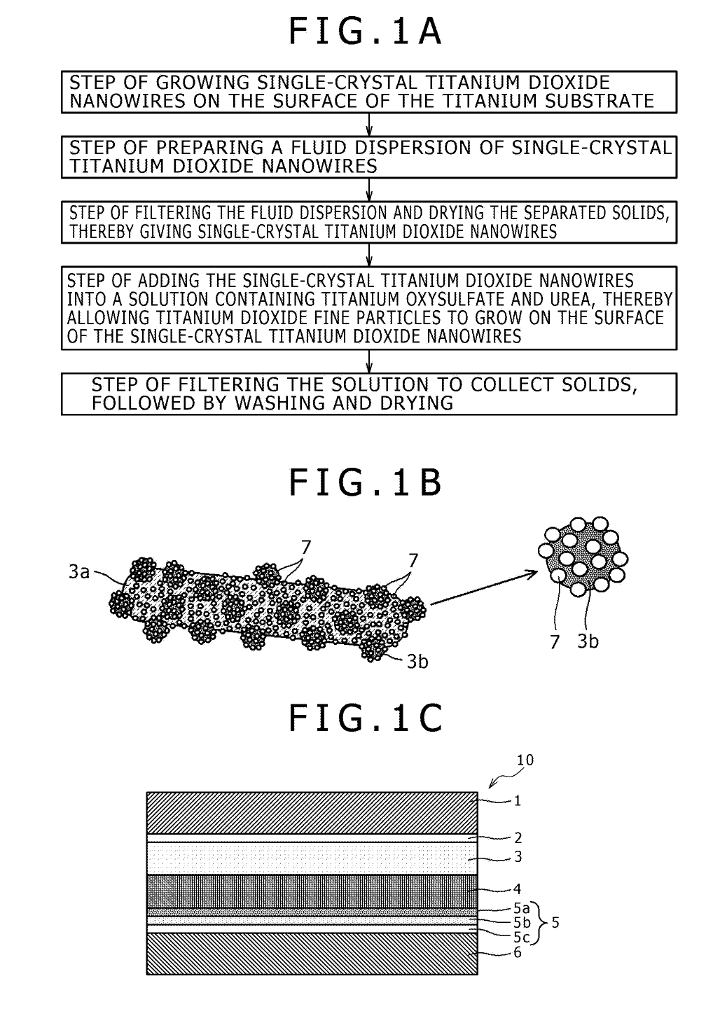

FIGS. 1A to 1C are diagrams illustrating the method for production of the titanium dioxide composite and the structure of the dye-sensitized solar cell incorporated with the titanium dioxide composite, both pertaining to the embodiment of the present invention. FIG. 1A is a flow sheet for production of the titanium dioxide composite. FIG. 1B is a schematic perspective view showing the titanium dioxide composite which supports the dye. FIG. 1C is a schematic sectional view showing the structure of the dye-sensitized solar cell.

It is noted from FIG. 1A that the method for production of the titanium dioxide composite includes (1) a step of growing single-crystal titanium dioxide nanowires of anatase type, (2) a step of preparing a fluid dispersion of single-crystal titanium dioxide nanowires, (3) a step of separating single-crystal titanium dioxide nanowires from the fluid dispersion of single-crystal titanium dioxide nanowires, (4) a step of growing titanium dioxide fine particles on the surface of single-crystal titanium dioxide nanowires, thereby performing the reaction for surface modifying treatment and (5) a step of recovering solids from the solution used for reaction for surface modifying treatment.

(1) Step of growing single-crystal titanium dioxide nanowires of anatase type:

This step accords with the method of Non-Patent Document and involves the heating and reacting of a cleaned titanium substrate together with an aqueous solution of sodium hydroxide in an autoclave. After reacting, the titanium substrate is rinsed with pure water, dipped in hydrochloric acid for ion exchange, rinsed again with pure water, and finally baked at a high temperature. In this way there are obtained single-crystal titanium dioxide nanowires of anatase type which are oriented perpendicularly to the surface of the titanium substrate.

(2) Step of preparing a fluid dispersion of single-crystal titanium dioxide nanowires:

This step is intended to separate the single-crystal titanium dioxide nanowires from the titanium substrate and then prepare a fluid dispersion of single-crystal titanium dioxide nanowires.

(3) Step of separating single-crystal titanium dioxide nanowires from the fluid dispersion of single-crystal titanium dioxide nanowires:

This step is intended to filter off the fluid dispersion of single-crystal titanium dioxide nanowires and to dry the thus separated solids. In this way there are obtained the single-crystal titanium dioxide nanowires in powder form.

(4) Step of growing titanium dioxide fine particles on the surface of single-crystal titanium dioxide nanowires, thereby performing the reaction for surface modifying treatment:

This step is intended to perform the reaction to form titanium dioxide fine particles on the surface of single-crystal titanium dioxide nanowires in powder form, thereby giving the surface-modified single-crystal titanium dioxide nanowires. This reaction accords with the method described in Non-Patent Document 1. The reaction for surface modifying treatment starts with dissolving titanium oxysulfate (TiOSO₄) in hydrochloric acid and adding urea (NH₂CONH₂) to the resulting solution, thereby preparing the solution for surface modifying treatment. In this solution are dipped the single-crystal titanium dioxide nanowires in powder form obtained as mentioned above with heating for a prescribed period of time, so that surface modification is accomplished.

(5) Step of recovering solids from the solution used for reaction for surface modifying treatment:

This step follows the reaction for surface modifying treatment. It is intended to filter the solution used for the reaction for surface modifying treatment so as to recover solids from the solution. The recovered solids are washed and dried.

The foregoing steps yield the titanium dioxide composite as desired, which is composed of single-crystal titanium dioxide nanowires in powder form which carry titanium dioxide fine particles formed on the surface thereof.

The above-mentioned steps (4) and (5) may be replaced by the steps (4′) and (5′) mentioned below.

(4′) Step of preparing a substrate with a precursor of the semiconductor layer and then dipping this substrate in the solution for reaction for surface modifying treatment, which has been prepared in the step (4). In the first part of this step, a fluid dispersion is prepared which contains single-crystal titanium dioxide nanowires in powder form and then it is applied onto the surface of the transparent electrode 2 formed on the transparent substrate 1. Upon drying, there is obtained the substrate with a precursor of the semiconductor layer 3. In the second part of this step, the substrate with a precursor of the semiconductor layer 3 is dipped in the solution for reaction for surface modifying treatment, which has been prepared in the step (4), so that the precursor for the semiconductor layer is impregnated with the solution for reaction for surface modifying treatment. In this way, the reaction for surface modifying treatment is accomplished which grows the titanium dioxide fine particles of anatase type on the surface of the single-crystal titanium dioxide nanowires.
(5′) This step follows the reaction for surface modifying treatment which has been carried out in the step (4′). In this step, the substrate with a precursor for the semiconductor layer is removed from the solution for the reaction for surface modifying treatment and then washed and dried as such.

The foregoing steps form the titanium dioxide composite, which is composed of single-crystal titanium dioxide nanowires in powder form carrying titanium dioxide fine particles formed on the surface thereof, on the surface of the transparent electrode 2 on the transparent substrate 1.

The semiconductor layer 3, which is made up of the titanium dioxide composite supporting a dye, can be prepared in the following manner.

The titanium dioxide composite prepared by the foregoing steps (4) and (5) is made into a fluid dispersion, and this fluid dispersion is applied to the surface of the transparent electrode 2 on the transparent substrate 1, followed by drying and baking at a high temperature. Baking should be accomplished at a temperature not exceeding the critical point for the phase transition from anatase type to rutile type of the titanium dioxide nanowires and titanium dioxide fine particles constituting the titanium dioxide composite.

Alternatively, after the foregoing steps (4′) and (5′) have been carried out to form the titanium dioxide composite on the surface of the transparent electrode 2 on the transparent substrate 1, the resulting product is baked at a temperature not exceeding the critical point for the phase transition from anatase type to rutile type.

The baking mentioned above forms the semiconductor layer 3 of titanium dioxide composite on the surface of the transparent electrode 2 on the transparent substrate 1. The resulting product is subsequently dipped in a solution containing the dye 7, so that the semiconductor layer 3 adsorbs the dye 7.

The titanium dioxide composite supporting the dye is constructed as shown in FIG. 1B and a partly enlarged view thereof. It is to be noted that a number of titanium dioxide fine particles 3b are formed on the surface of single-crystal titanium dioxide nanowires 3a, and molecules of the dye 7 are supported on the surface of both the single-crystal titanium dioxide nanowires 3a and the titanium dioxide fine particles 3b.

The following is a description of one example of the dye-sensitized solar cell which has the semiconductor layer 3 of titanium dioxide composite supporting a dye, as shown in FIG. 1C.

It is to be noted from FIG. 1C that the dye-sensitized solar cell 10 is composed of the transparent substrate 1 of glass or the like, the transparent electrode 2, the semiconductor layer 3, the electrolyte layer 4, the counter electrode 5, the counter substrate 6, and the sealing material (not shown). The semiconductor layer 3 functions as the working electrode or negative electrode. The counter electrode 5, which functions as the positive electrode, is composed of the platinum layer 5a, the chromium layer 5b, and the transparent conductive layer 5c.

The transparent electrode 2 is a negative electrode in the form of transparent conductive layer of FTO (fluorine-doped tin (iv) oxide (SnO₂). The semiconductor layer 3 is a porous one, which is formed from the above-mentioned titanium dioxide composite. The first step to form the semiconductor layer 3 is preparation of the fluid dispersion of the titanium dioxide by the process shown in FIG. 1A. The resulting fluid dispersion is applied to the surface of the transparent electrode 2, followed by baking. The resulting porous layer undergoes dye-supporting treatment. In this way there is obtained the semiconductor layer 3 made up of the titanium dioxide composite supporting the dye 7, as shown in FIG. 1B.

The electrolyte layer 4 is placed between the semiconductor layer 3 and the counter electrode 5. It is formed from an organic electrolytic solution containing the redox pair of I⁻/I₃⁻ or the like. The counter electrode 5, which is formed on the counter substrate 6, is composed of the platinum layer 5a, the chromium layer 5b, and the transparent conductive layer 5c.

Upon exposure to light, the dye-sensitized solar cell 10 functions as a battery in which the counter electrode 5 and the transparent electrode 2 are equivalent to the positive electrode and the negative electrode, respectively. The dye-sensitized solar cell 10 functions on the principle described below if it employs the redox species of I⁻/I₃⁻ as the redox pair.

The sensitizing dye absorbs photons passing through the transparent substrate 1 and the transparent electrode 2. The absorption of photons excites electrons in the sensitizing dye 7 from their ground state to their excited state. The excited electrons enter the conduction band of the semiconductor layer 3 through the electrical linkage between the photosensitizing dye 7 and the semiconductor layer 3, so that they eventually arrive the transparent electrode 2 through the semiconductor layer 3.

On the other hand, the sensitizing dye 7, which has lost electrons, receives electrons from the reductant in the electrolyte layer 4 by the following reactions:

2I⁻→I₂+2e⁻ I₂+I⁻→I₃⁻

thereby giving rise to an oxidant (I₃⁻ as an aggregate of I₂ and I⁻) in the electrolyte layer 4. The resulting oxidant diffuses to reach the counter electrode 5 so as to receive electrons from the counter electrode 6 by the following reactions, which are reverse ones of the foregoing reactions.

I₃⁻→I₂+I⁻ I₂+2e⁻→2I⁻

Thus the oxidant is reduced to the original reductant.

The transparent electrode 2 sends out electrons to the external circuit, and these electrons accomplish electrical work in the external circuit and then return to the counter electrode 5. In this way, conversion from optical energy into electrical energy takes place without leaving any change in either the sensitizing dye 7 and the electrolyte layer 4.

The sensitizing dye 7 may be any substance that absorbs light in the visible region. Examples of such a substance include bipyridine complexes, terpyridine complexes, merocyanine dyes, porphyrin, and phthalocyanine.

Commonly used dyes include cis-bis(isothiocyanate)-N,N-bis(2,2′-bipyridyl-4,4′-dicarboxylic acid) ruthenium (ii) ditetrabutylammonium complex, which is one species of the bipyridine complexes (alias N719), cis-bis(isothiocyanate)bis(2,2′-bipyridyl-4,4′-dicarboxylic acid) ruthenium (ii) (alias N3), and tris(isothiocyanate) (2,2′:6′,2″-terpyridyl-4,4′,4″-tricarboxylic acid) ruthenium (ii) tritetrabutylammonium complex (alias black dye), which is one species of the terpyridine complexes.

The transparent conductive layer may be any conductive material which absorbs little sunlight in the visible region to the near infrared region. It may be formed from a highly conductive metal oxide, such as ITO (indium-tin oxide), tin oxide (including fluorine-doped one), and zinc oxide.

The transparent substrate may be any material which absorbs little sunlight in the visible region to the near infrared region. It may be formed from any heat resistant material such as quartz, BK7, and lead glass.

The solution containing the sensitizing dye, which is used for treatment to make the semiconductor layer 3 support the dye, is prepared by dissolution in any of the following solvents. Alcohols, nitrile-containing solvents, halogen-containing solvents, ethers, esters, ketones, carbonic esters, hydrocarbons, dimethylformamide, dimethylacetamide, dimethylsulfoxide, 1,3-dimethylimidazolinone, N-methylpyrrolidone, and water. These solvents may be used alone or in combination with one another.

The electrolyte layer 4 is formed from a solution containing a mixture of I₂ and an iodide (such as LiI, NaI, KI, CsI, MgI₂, CaI₂, CuI, tetraalkylammonium iodide, pyridinium iodide, and imidazolium iodide) or a mixture of Br₂ and bromide (such as LiBr). The solution also contains a solvent, such as ether compound, linear ether, alcohol, polyhydric alcohol, nitrile-compound, and carbonate compound.

The counter electrode 5 is formed from any conductive material, including metals such as platinum, gold, silver, copper, aluminum, rhodium, indium, and chromium and metal oxides such as ITO (indium-tin oxide), tin oxide (including fluorine-doped tin oxide), and zinc oxide.

The gap between the transparent substrate 1 and the counter electrode 6 is sealed with a sealing material, such as thermoplastic resin, photocurable resin, and glass frit, so that the electrolyte layer 4 does not leak and evaporate from the solar cell.

The following is a detailed description of the examples that demonstrate the titanium dioxide composite and the dye-sensitized solar cell incorporated therewith.

### EXAMPLES

### [Synthesis of Titanium Dioxide Nanowires]

The titanium dioxide nanowires, which are fundamental constituents of the titanium dioxide composite, are synthesized in the following manner. In this example, single-crystal titanium dioxide nanowires were synthesized as follows according to the method mentioned in Non-Patent Document 2.

A piece of metallic titanium foil (100 μm thick, made by NILACO Corporation) was ultrasonically cleaned for 30 minutes in a mixture of acetone, isopropyl alcohol (IPA), and pure water in equal amounts. The cleaned foil was heated at 220° C. for 12 hours in an autoclave containing a 1 M aqueous solution of sodium hydroxide. After rinsing with pure water, the titanium foil underwent ion exchange reaction in 0.6 M hydrochloric acid for one hour. The titanium foil was rinsed again with pure water and then baked at 650° C. for two hours in the atmospheric air. Thus there were obtained single-crystal titanium dioxide nanowires which are vertically oriented on the titanium foil.

The baked titanium foil was exposed to ultrasonic waves (40 kHz, 300 W) for three minutes in IPA held in an ultrasonic dispersing machine, so that it releases single-crystal titanium dioxide nanowires from it for dispersion in IPA. The fluid dispersion of nanowires was filtered through a nitrocellulose filter (47 mm in diameter, having a pore diameter of 0.22 μm, made by Nihon Millipore K.K.). The filter paper was air-dried. Thus there were obtained titanium dioxide nanowires in powder form. This powder was found to have a specific surface area of 11.9 m²/g (measured by BET method).

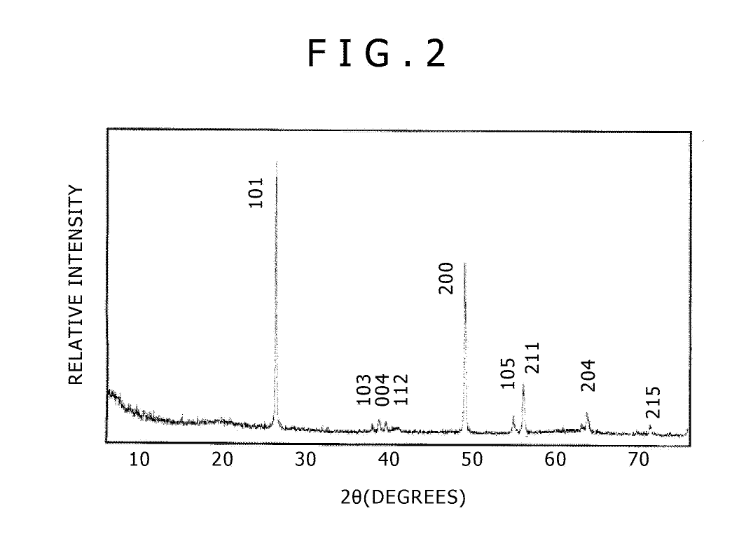

FIG. 2 is a diagram illustrating an X-ray diffraction pattern of the titanium dioxide nanowires in powder form pertaining to an embodiment of the present invention. In FIG. 2, the abscissa represents the 2θ (degrees) and the ordinate represents the relative intensity.

The X-ray diffraction pattern of the titanium dioxide nanowires in powder form does not show the diffraction peaks at 2θ=ca. 36° and 42° which are characteristic of titanium dioxide of rutile type. This indicates that the titanium dioxide nanowires are of anatase type.

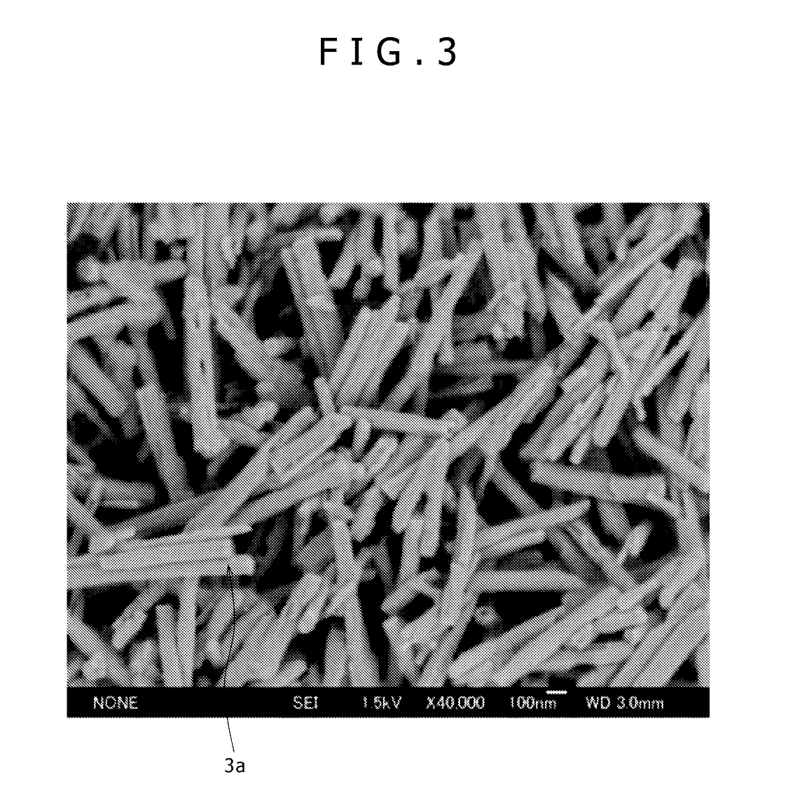

FIG. 3 is a diagram illustrating a micrograph (with a magnification of 40000), taken by a scanning electron microscope (SEM), of the titanium dioxide nanowires pertaining to an embodiment of the present invention.

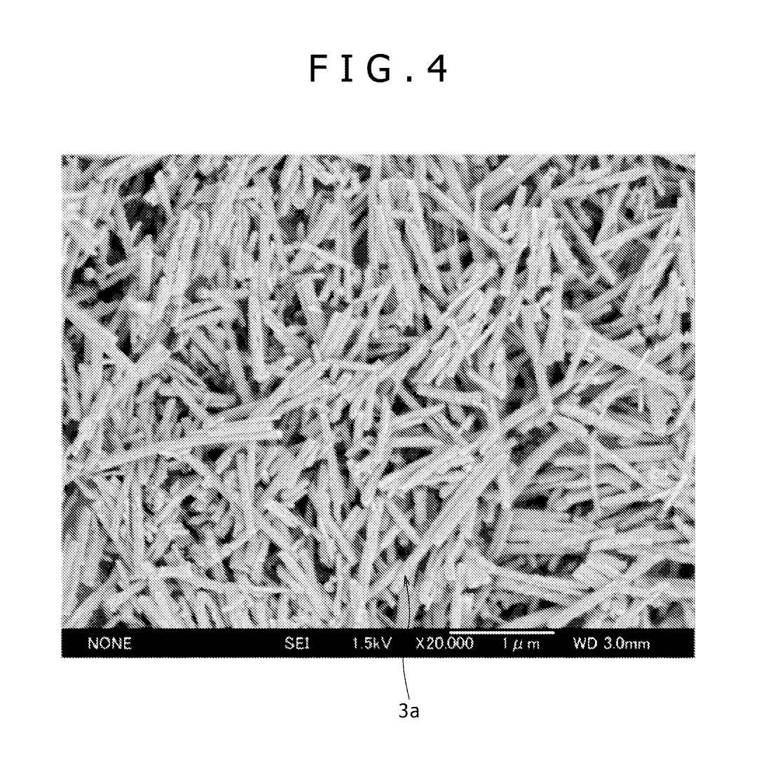

FIG. 4 is a diagram illustrating a micrograph (with a magnification of 20000), taken by a scanning electron microscope (SEM), of the titanium dioxide nanowires pertaining to an embodiment of the present invention.

FIGS. 3 and 4 are SEM micrographs of the titanium dioxide nanowires which do not yet undergo surface modifying treatment. The SEM micrograph in FIG. 3 indicates that the titanium dioxide nanowires have an average diameter of 94 nm, with a standard deviation (σ) of 8 nm (for N=20, N being the number of measurements).

Since the titanium dioxide nanowires pertaining to this embodiment were synthesized in the same way as mentioned in Non-Patent Document 2, they have a diameter ranging from about 40 nm to 110 nm, depending on the duration of synthesis, as shown in FIG. 4 in Non-Patent Document 2.

The SEM micrograph in FIG. 4 indicates that the titanium dioxide nanowires have an average length of 980 nm, with a standard deviation (σ) of 320 nm (for N=30, N being the number of measurements). The maximum and minimum lengths are 1800 nm and 480 nm, respectively.

This embodiment applies ultrasonic waves to the titanium foil on which the titanium dioxide nanowires are formed and which is placed in IPA for removal of titanium dioxide nanowires, and this step is followed by filtration and drying to obtain the titanium dioxide nanowires in powder form. Therefore, it is considered that many of the thus obtained titanium dioxide nanowires in powder form are not longer than the titanium dioxide nanowires actually formed on the titanium foil. In fact, the measured lengths broadly range and the standard deviation is large, and the average length of the titanium dioxide nanowires of 980 nm seems to be much shorter than the average actual length.

Since this embodiment follows the method described in Non-Patent Document 2 for synthesis of titanium dioxide nanowires, the resulting titanium dioxide nanowires become longer according as the duration of synthesis increases as shown in FIG. 4 of Non-Patent Document 2. Therefore, it would be possible to obtain the titanium dioxide nanowires in powder form which are nearly as long as the titanium dioxide nanowires actually formed on the titanium foil if the duration of synthesis is extended and the application of ultrasonic waves is carried out under adequate conditions that the force which shorten the titanium dioxide nanowires formed on the titanium foil would not be generated for the titanium dioxide nanowires to be released from the titanium foil without being broken.

### [Preparation of Semiconductor Electrode (or Semiconductor Layer)]

The following is a description of the procedure to prepare the semiconductor electrode including the semiconductor layer 3 which is formed on the transparent electrode 2 on the transparent substrate 1.

The semiconductor layer 3 made up of the titanium dioxide composite is prepared by the steps (1), (2), (3), (4) and (5), or the steps (1), (2), (3), (4′), and (5′), which were mentioned above. The following description concerns with the second ones.

In the step (3), there were obtained the single-crystal titanium dioxide nanowires in powder form by means of an ultrasonic dispersing machine. The nanowires were dispersed into IPA to prepare a fluid dispersion containing about 1 g/L of nanowires. The resulting fluid dispersion was applied by spraying to an FTO substrate (having a sheet resistance of 10Ω/□, an area of 25 mm by 15 mm, and a thickness of 1.1 mm, made by Nippon Sheet Glass Co., Ltd.) The FTO substrate is composed of a glass substrate (the transparent substrate 1) and FTO (the transparent electrode 2). Upon heating and drying at 100° C., there were obtained several samples of FTO substrates, each having a semiconductor electrode (the semiconductor layer 3) about 3 μm thick.

Some of these samples were baked at 150° C. or 510° C. for 30 minutes in the atmospheric air. There were obtained FTO substrates having the semiconductor electrode-1 for comparison or the semiconductor electrode-3 for comparison. The remainder of the samples underwent surface modification in the following way.

### [Treatment for Surface Modification of Titanium Dioxide Nanowires]

Treatment for surface modification was performed on the single-crystal titanium dioxide nanowires in the following way according to the method described in Non-Patent Document 1.

A solution for surface modification of the semiconductor electrode (or the semiconductor layer 3) on the FTO substrate was prepared as follows. First, 552 mg of titanium oxysulfate (TiOSO₄) was dissolved in 200 mL of 0.3 M hydrochloric acid. After complete dissolution by stirring for 1 hour, 24 g of urea (NH₂CONH₂) was added with stirring.

The FTO substrate having the semiconductor electrode (or the semiconductor layer 3) formed thereon was dipped in the solution of surface modification prepared as mentioned above. Dipping was performed at 100° C. for 60 minutes, 90 minutes, or 180 minutes. After dipping, the FTO substrate was rinsed with pure water.

In this way there were obtained several samples of the FTO substrates, each having the semiconductor electrode (or the semiconductor layer 3) composed of single-crystal titanium dioxide nanowires surface-modified with titanium dioxide fine particles.

Some of these samples were baked at 150° C. for 30 minutes in the atmospheric air. Those samples which underwent dipping for 60 minutes are designated as the FTO substrates having the semiconductor layer-1 formed thereon, and those samples which underwent dipping for 90 minutes are designated as the FTO substrates having the semiconductor layer-2 formed thereon.

The remainders of the samples were baked at 510° C. for 30 minutes in the atmospheric air. Those samples which underwent dipping for 90 minutes are designated as the FTO substrates having the semiconductor layer-3 formed thereon, and those samples which underwent dipping for 180 minutes are designated as the FTO substrates having the semiconductor layer-4 formed thereon.

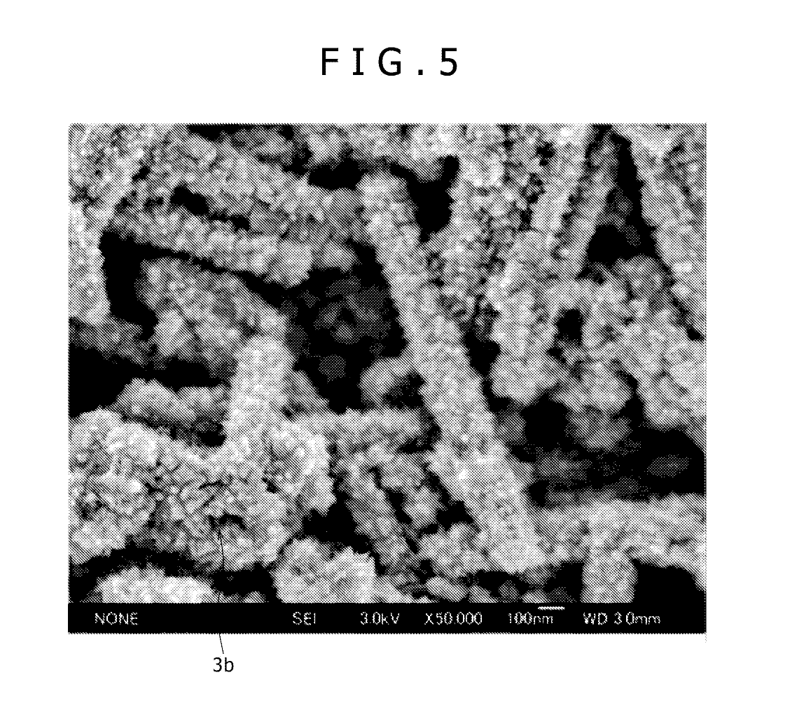

FIG. 5 is a diagram illustrating a micrograph (with a magnification of 50000), taken by a scanning electron microscope (SEM), of the titanium dioxide nanowires, which have undergone the surface modifying treatment for 90 minutes, pertaining to an embodiment of the present invention.

It is noted from FIG. 5 that the semiconductor electrode-3 (or the semiconductor layer 3 of surface-modified titanium dioxide nanowires) on the FTO substrate, which has undergone surface modification treatment for 90 minutes has the single-crystal titanium dioxide nanowires have titanium dioxide fine particles (5 to 50 nm in diameter) formed on the surface thereof.

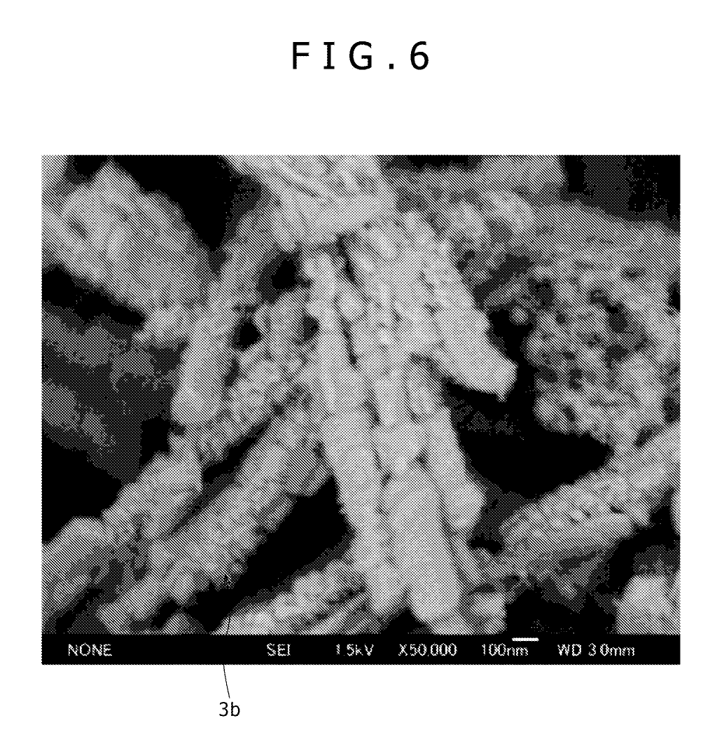

FIG. 6 is a diagram illustrating a micrograph (with a magnification of 50000), taken by a scanning electron microscope (SEM), of the titanium dioxide nanowires, which have undergone the surface modifying treatment for 180 minutes, pertaining to an embodiment of the present invention.

It is noted from FIG. 6 that the semiconductor electrode-3 (or the semiconductor layer 3 of surface-modified titanium dioxide nanowires) on the FTO substrate, which has undergone surface modification treatment for 180 minutes has the single-crystal titanium dioxide nanowires have titanium dioxide fine particles (20 to 150 nm in diameter) formed on the surface thereof. This diameter is larger than that of the titanium dioxide fine particles shown in FIG. 5.

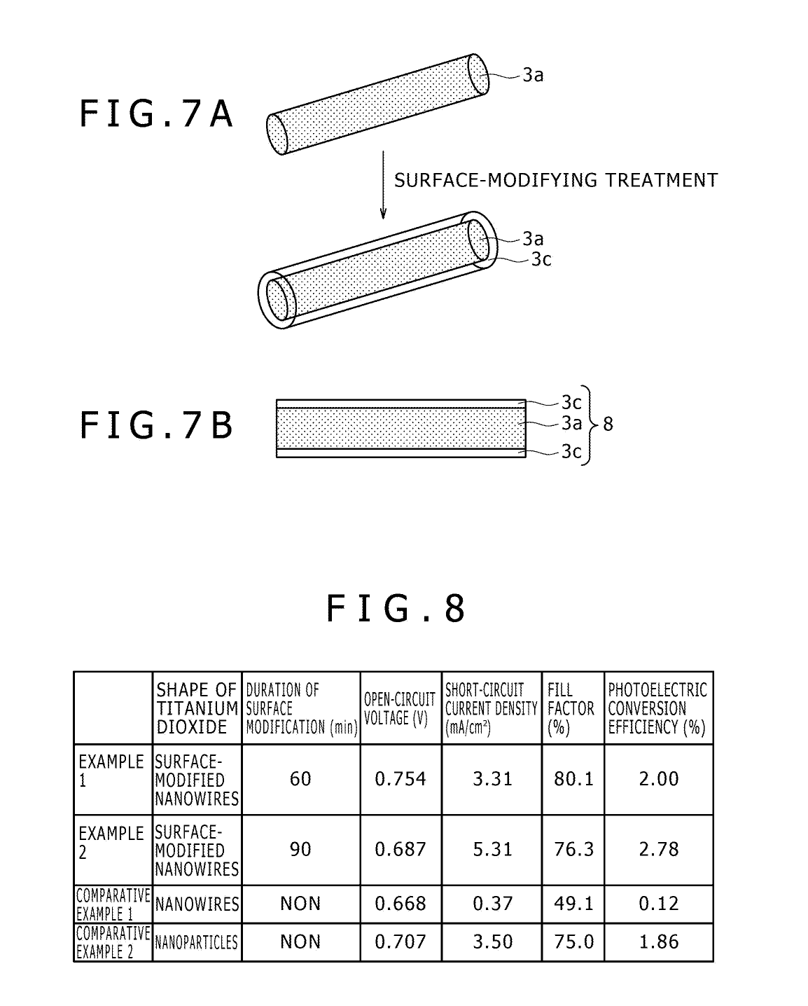

FIGS. 7A and 7B are schematic perspective views showing the structure of the surface-modified titanium dioxide nanowires (the titanium dioxide composite), pertaining to an embodiment of the present invention.

The surface-modified titanium dioxide nanowires (or the titanium dioxide composite) shown in FIGS. 5 and 6 are constructed of the single-crystal titanium dioxide nanowires 3a of anatase type as shown in FIGS. 3 and 4 and the titanium dioxide fine particles (or fine crystals) 3b of anatase type which form the continuous or uncontinuous modifying layer 3c on the surface of the nanowires as shown in FIGS. 7A and 7B.

### [Change in Specific Surface Area Due to Surface Modification of Titanium Dioxide Nanowires]

A portion of the single-crystal titanium dioxide nanowires in powder form, which have been obtained in the foregoing step (3), was added as such to the solution for surface modifying treatment mentioned above. The resulting fluid dispersion was stirred at 100° C. for 180 minutes, and then it was filtered through a nitrocellulose filter (47 mm in diameter, having a pore diameter of 0.22 μm, made by Nihon Millipore K.K. The filter paper was air-dried. Thus there were obtained surface-modified titanium dioxide nanowires (or the titanium dioxide composite). This titanium dioxide composite was found to have a specific surface area of 27.6 m²/g, which is 2.3 times larger than that (11.9 m²/g) of the single-crystal titanium dioxide nanowires without surface modification. Thus, the titanium dioxide nanowires greatly increase in specific surface area by surface modification with titanium dioxide fine particles.

### [Preparation of Semiconductor Electrode (or Semiconductor Layer) for Comparison]

The following is a description of the procedure to prepare the semiconductor electrode (or semiconductor layer) for comparison which is formed on the transparent electrode 2 on the transparent substrate 1.

First, titanium isopropoxide (125 mL) was slowly added dropwise to 0.1 M aqueous solution of nitric acid (750 mL) with stirring at room temperature. The resulting mixture was stirred for eight hours in a thermostat at 80° C. In this way there was obtained a turbid translucent sol solution. This sol solution was allowed to cool to room temperature and then filtered through a glass filter. An aliquot of 700 mL was taken from the filtrate, and it underwent hydrothermal treatment at 220° C. for 12 hours in an autoclave. The resulting liquid underwent dispersion for 1 hour by means of an ultrasonic dispersing machine. The resulting fluid dispersion was concentrated at 40° C. by means of an evaporator so that the concentration of titanium dioxide was adjusted to 8 wt %. The concentrated fluid dispersion was applied by spraying to the FTO substrate so as to prepare the semiconductor electrode (or semiconductor layer). The semiconductor electrode (or semiconductor layer) was baked at 150° C. and 510° C. in the atmospheric air. In this way there were obtained samples of the FTO substrates, each having the semiconductor electrode-2 for comparison or the semiconductor electrode-4 for comparison.

### [Production of Dye-Sensitized Solar Cell]

The dye-sensitized solar cell constructed as shown in FIG. 1C was produced in the following way by incorporation with the FTO substrate on which is formed any of the above-mentioned semiconductor electrode-1 to -4 and semiconductor electrode-1 to -4 for comparison.

### (Step for the Semiconductor Electrode to Support the Dye)

The FTO substrate, which has the semiconductor electrode (semiconductor layer) formed thereon, was dipped in a solution containing 0.3 mM of cis-bis(isothiocyanate)-N,N-bis(2,2′-dipyridyl-4,4′-dicarboxylic acid) ruthenium (ii) ditetrabutylammonium salt dissolved in tert-butyl alcohol and acetonitrile mixed in equal volume, at room temperature for 24 hours, so that the FTO substrate supports the dye. The thus treated semiconductor electrode was rinsed with acetonitrile containing 4-tert-butylpyridine and then with acetonitrile. This step was followed by drying in the dark.

### (Counter Electrode)

The counter electrode 5 was prepared by coating the transparent conductive layer (FTO) 5c, which is formed on the counter substrate 6 (FTO substrate), sequentially with the chromium layer 5b (500 Å thick) and the platinum layer 5a (1000 Å thick) by sputtering, and then spray-coating the platinum layer 5a with a solution of chloroplatinic acid in IPA, followed by baking at 385° C. for 15 minutes.

### (Electrolyte Solution)

The electrolyte composition was prepared from 0.1 mol/L of sodium iodide (NaI), 1.4 mol/L of 1-propyl-2,3-dimethylimidazolium iodide (DMPImI), 0.15 mol/L of iodine (I₂), and 0.2 mol/L of 4-tert-butylpyridine (TBP) dissolved in 2 g of methoxypropionitrile (MPM).

The thus prepared electrolyte solution was dropped on the semiconductor electrode (semiconductor layer 3), which was subsequently combined with the counter electrode, with a silicone rubber spacer (30 μm thick) interposed between them. In this way there was produced the dye-sensitized solar cell.

Incidentally, the dye-sensitized solar cells pertaining to the embodiment and for comparison are incorporated with any of the following semiconductor electrodes.

### Example 1

The solar cell in this example is incorporated with the semiconductor electrode-1, which is 3 μm thick and has a cell resistance of 79.33Ω. The cell resistance was measured with Solar Simulator YS-200AA and IV measuring system made by Yamashita Denso. (The same shall apply hereinafter.)

### Example 2

The solar cell in this example is incorporated with the semiconductor electrode-2, which is 3 μm thick and has a cell resistance of 57.08Ω.

### Example 3

The solar cell in this example is incorporated with the semiconductor electrode-3, which is 3 μm thick and has a cell resistance of 81.80Ω.

### Example 4

The solar cell in this example is incorporated with the semiconductor electrode-4, which is 3 μm thick and has a cell resistance of 41.70Ω.

### Comparative Example 1

The solar cell in this example is incorporated with the semiconductor electrode-1 for comparison, which is 3 μm thick and has a cell resistance of 1574.08Ω.

### Comparative Example 2

The solar cell in this example is incorporated with the semiconductor electrode-2 for comparison, which is 3 μm thick and has a cell resistance of 78.96Ω.

### Comparative Example 3

The solar cell in this example is incorporated with the semiconductor electrode-3 for comparison, which is 3 μm thick and has a cell resistance of 96.50Ω.

### Comparative Example 4

The solar cell in this example is incorporated with the semiconductor electrode-4 for comparison, which is 3 μm thick and has a cell resistance of 52.73Ω.

### [Performance of the Dye-Sensitized Solar Cell]

The dye-sensitized solar cells produced in Examples 1 to 4 and Comparative Examples 1 to 4 mentioned above were examined for their characteristic properties listed below by irradiation with artificial sunlight (AM 1.5, 100 mW/cm²). Current-voltage curve, short-circuit current I_{sc}, open-circuit voltage V_{oc}, fill factor FF, and photoelectric conversion efficiency η.

The short-circuit current I_{sc} is a current which flows through a conductor short-circuiting the anode and cathode of the solar cell. It is represented in terms of short-circuit current density J_{sc} per unit area of the solar cell. The open-circuit voltage V_{oc} is a voltage that appears across the anode and cathode of the solar cell which are not connected to anything.

The fill factor FF (which is also called form factor) is one of the parameters to specify the characteristics of the dye-sensitized solar cell. An ideal solar cell gives a current-voltage curve in which the output voltage equal to the open-circuit voltage V_{oc} remains constant until the output current reaches the same magnitude as the short-circuit current I_{sc}. However, an actual dye-sensitized solar cell gives a current-voltage curve which deviates from an ideal one on account of the internal resistance. The fill factor FF is defined by the ratio of A/B, where A denotes the area of the region surrounded by the actual current-voltage curve and the x axis and y axis, and B denotes the area of the region surrounded by the ideal current-voltage curve and the x axis and y axis. In other words, the fill factor FF indicates the degree of deviation from the ideal current-voltage curve. It is used to calculate the actual photoelectric conversion efficiency η.

The fill factor FF is defined by (Vₘₐₓ·Iₘₐₓ)/(V_{oc}·I_{sc}), where Vₘₐₓ and Iₘₐₓ denote respectively the voltage and current at the operating point for the maximum output power. The photoelectric conversion efficiency η is defined by V_{oc}·J_{sc}·FF.

FIG. 8 is a diagram illustrating the characteristic properties of the dye-sensitized solar cell incorporated with the semiconductor layer (electrode) which has undergone the baking treatment at 150° C., pertaining to an embodiment of the present invention.

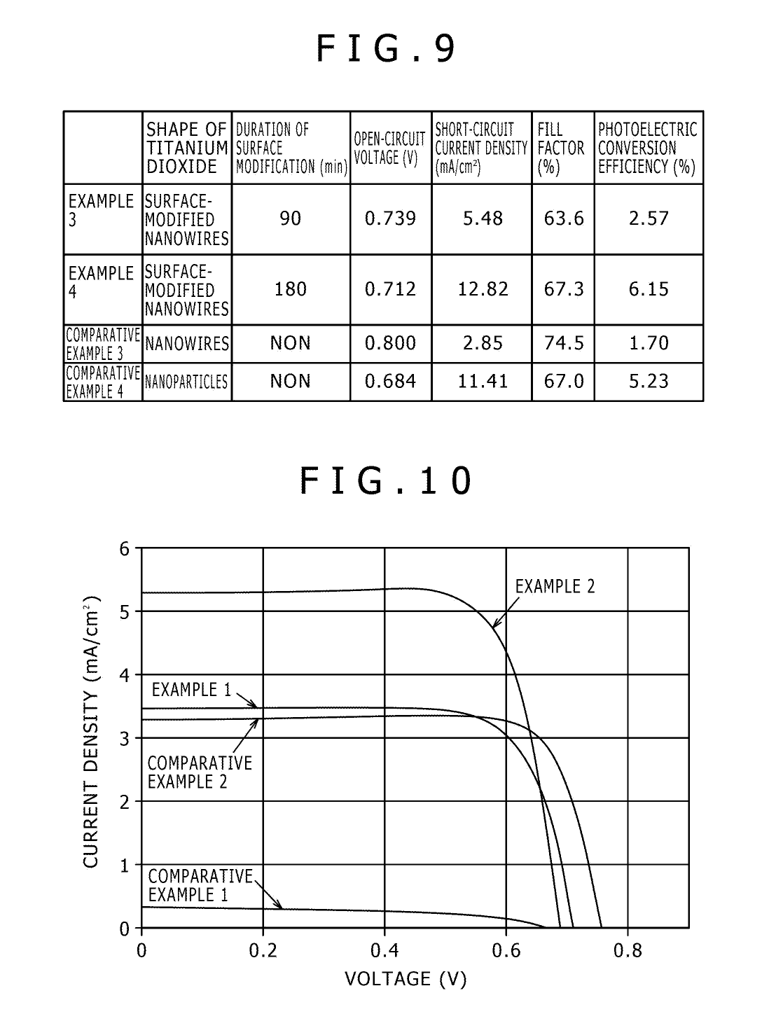

FIG. 9 is a diagram illustrating the characteristic properties of the dye-sensitized solar cell incorporated with the semiconductor layer (electrode) which has undergone the baking treatment at 510° C., pertaining to an embodiment of the present invention.

FIG. 10 is a diagram illustrating the current-voltage characteristics of the dye-sensitized solar cell incorporated with the semiconductor layer (electrode) which has undergone the baking treatment at 150° C., pertaining to an embodiment of the present invention. The abscissa represents voltage (V) and the ordinate represents current density (mA/cm²).

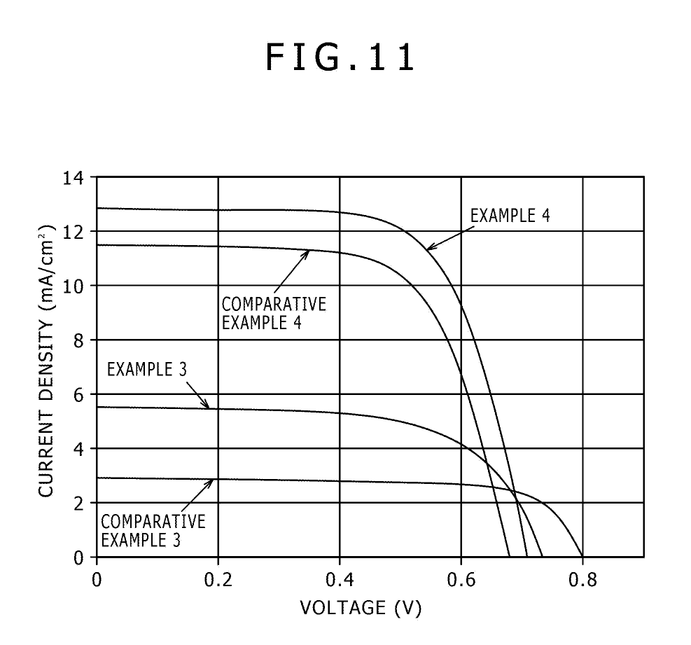

FIG. 11 is a diagram illustrating the current-voltage characteristics of the dye-sensitized solar cell incorporated with the semiconductor layer (electrode) which has undergone the baking treatment at 510° C., pertaining to an embodiment of the present invention. The abscissa represents voltage (V) and the ordinate represents current density (mA/cm²).

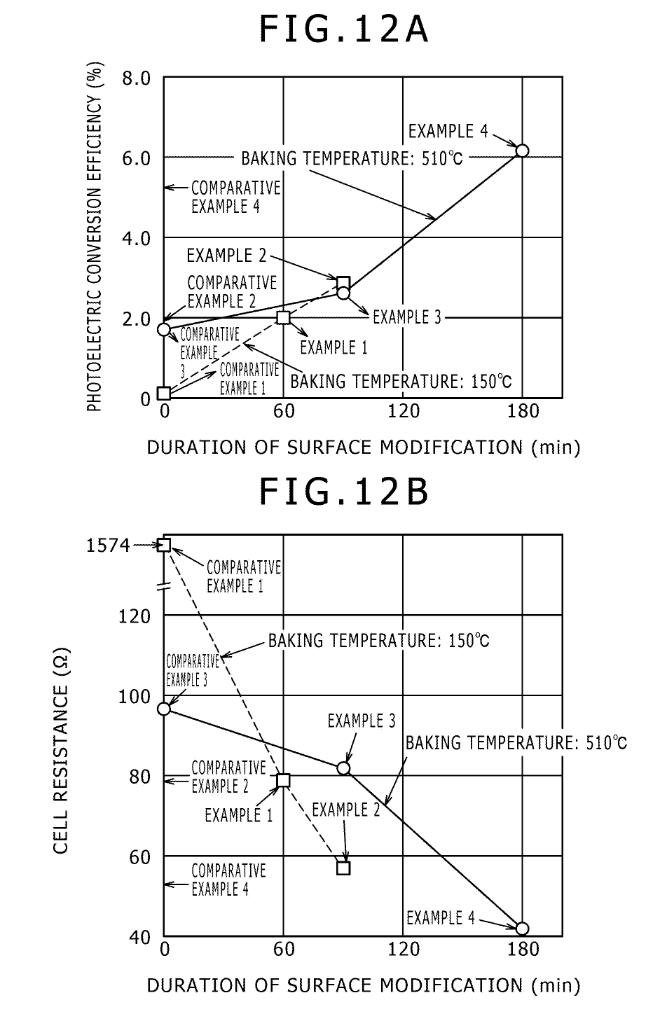

FIGS. 12A and 12B are diagrams illustrating how the solar cell varies in photoelectric conversion efficiency and cell resistance depending on the duration of the surface treatment of the single-crystal titanium dioxide nanowires and the temperature of the baking treatment for the semiconductor layer, pertaining to an embodiment of the present invention. This diagram has been drawn by plotting data in FIGS. 8 and 9.

FIG. 12A is a diagram illustrating the relation among the duration of surface modification for single-crystal titanium dioxide nanowires, the baking temperature of the semiconductor layer, and the photoelectric conversion efficiency of the solar cell. The abscissa represents the duration (minutes) of surface modification for single-crystal titanium dioxide nanowires, and the ordinate represents the photoelectric conversion efficiency (%). FIG. 12B is a diagram illustrating the relation among the duration of surface modification for single-crystal titanium dioxide nanowires, the baking temperature of the semiconductor layer, and the cell resistance. The abscissa represents the duration (minutes) of surface modification for single-crystal titanium dioxide nanowires, and the ordinate represents the cell resistance (Ω).

It is noted from FIGS. 8 and 10 that the solar cells according to Examples 1 and 2 and Comparative Examples 1 and 2, which are incorporated with the semiconductor layer (electrode) baked at 150° C., vary in short-circuit current density J_{sc} obtained from the data of current-voltage curve such that it increases in the order of Comparative Example 1, Examples 1, Comparative Example 2, and Example 2, and also vary in open-circuit voltage V_{oc} such that it increases in the order of Comparative Example 1, Example 1, Comparative Example 2, and Example 2, and also vary in fill factor FF such that it increases in the order of Comparative Example 1, Comparative Example 2, Example 2, and Example 1. In addition, the solar cell according to Example 1, which is incorporated with the semiconductor layer obtained by surface modification for 90 minutes on the titanium dioxide nanowires, gave the highest value of photoelectric conversion efficiency.

It is noted from FIGS. 8, 10 and 12A that the solar cell according to Example 1, which is incorporated with the semiconductor layer obtained by surface modification for 60 minutes on the titanium dioxide nanowires, gave the photoelectric conversion efficiency which is about 17 times that of the solar cell according to Comparative Example 1, which is incorporated with the semiconductor layer obtained without surface modification on the titanium dioxide nanowires. It is also noted that the solar cell according to Example 2, which is incorporated with the semiconductor layer obtained by surface modification for 90 minutes on the titanium dioxide nanowires, gave the photoelectric conversion efficiency which is about 23 times that of the solar cell according to Comparative Example 1. This suggests that surface modification for the titanium dioxide nanowires produces a significant effect on improvement in photoelectric conversion efficiency.

The solar cell according to Example 2 gives a photoelectric conversion efficiency which is about 1.5 times that the solar cell according to Comparative Example 2, which is incorporated with the semiconductor layer composed of titanium nanoparticles.

It is noted from FIGS. 9 and 11 that the solar cells according to Examples 3 and 4 and Comparative Examples 3 and 4, which are incorporated with the semiconductor layer (electrode) baked at 510° C., vary in short-circuit current density J_{sc} obtained from the data of current-voltage curve such that it increases in the order of Comparative Example 3, Examples 3, Comparative Example 4, and Example 4, and also vary in open-circuit voltage V_{oc} such that it increases in the order of Comparative Example 4, Example 4, Example 3, and Comparative Example 3, and also vary in fill factor FF such that it increases in the order of Example 3, Comparative Example 4, Example 4, and Comparative Example 3. In addition, the solar cell according to Example 4, which is incorporated with the semiconductor layer obtained by surface modification for 180 minutes on the titanium dioxide nanowires, gave the highest value of photoelectric conversion efficiency.

It is noted from FIGS. 9, 11 and 12A that the solar cell according to Example 3, which is incorporated with the semiconductor layer obtained by surface modification for 90 minutes on the titanium dioxide nanowires, gave the photoelectric conversion efficiency which is about 1.5 times that of the solar cell according to Comparative Example 3, which is incorporated with the semiconductor layer obtained without surface modification on the titanium dioxide nanowires. It is also noted that the solar cell according to Example 4, which is incorporated with the semiconductor layer obtained by surface modification for 180 minutes on the titanium dioxide nanowires, gave the photoelectric conversion efficiency which is about 3.6 times that of the solar cell according to Comparative Example 3. This suggests that surface modification for the titanium dioxide nanowires produces a significant effect on improvement in photoelectric conversion efficiency.

The solar cell according to Example 4 gave the photoelectric conversion efficiency which is about 1.2 times that of the solar cell according to Comparative Example 4, which is incorporated with the semiconductor layer composed of titanium nanoparticles. This suggests that Example 4 achieves a good improvement in photoelectric conversion efficiency.

The solar cell according to Example 4 gave the photoelectric conversion efficiency which is about 2.2 times that of the solar cell according to Example 2. This improvement is due to the effect produced by extending the duration of surface modification and increasing the baking temperature. FIG. 12B is a diagram illustrating the relation among the duration of surface modification for single-crystal titanium dioxide nanowires, the baking temperature of the semiconductor layer, and the cell resistance. The abscissa represents the duration (minutes) of surface modification for single-crystal titanium dioxide nanowires, and the ordinate represents the cell resistance (Ω).

The solar cells according to Examples 1 and 2 and Comparative Examples 1 and 2, which are incorporated with the semiconductor layer (electrode) baked at 150° C., were examined for cell resistance. The cell resistance in Example 1 is about 1/20 times that in Comparative Example 1 and equal to that in Comparative Example 2, and the cell resistance in Example 2 is about 1/28 times that in Comparative Example 1 and about 1/1.5 times that in Comparative Example 2.

The solar cells according to Examples 3 and 4 and Comparative Examples 3 and 4, which are incorporated with the semiconductor layer (electrode) baked at 510° C., were examined for cell resistance. The cell resistance in Example 3 is about 1/1.2 times that in Comparative Example 3 and about 1.6 times that in Comparative Example 4, and the cell resistance in Example 4 is about 1/2.3 times that in Comparative Example 3 and about 1/1.3 times that in Comparative Example 4.

Comparison of Examples 1 and 2 with Comparative Example 1, or comparison of Examples 3 and 4 with Comparative Example 3 reveals that the cell resistance is small on account of baking at 150° C. or 510° C.

It is also noted from FIGS. 12A and 12B that the solar cell of Example 4 has the highest value of photoelectric conversion efficiency and the lowest value of cell resistance among the solar cells of Examples 1 to 4 and Comparative Examples 1 to 4. This suggests that reduction in cell resistance greatly contributes to improvement in photoelectric conversion efficiency.

The embodiments of the present invention have been described above. They are not intended to restrict the scope of the present invention but may be variously changed and modified based on the technical idea of the present invention.

The present invention provides a titanium dioxide composite to form the semiconductor layer of the photoelectric conversion device, a method for production thereof, and a photoelectric conversion device having a high photoelectric conversion efficiency.

The present application contains subject matter related to that disclosed in Japanese Priority Patent Application JP 2010-111242 filed in the Japan Patent Office on May 13, 2010, the entire content of which is hereby incorporated by reference.

What is claimed is:

1. A method for production of a titanium dioxide composite, said method comprising the steps of:
preparing titanium dioxide nanowires;
dipping said titanium dioxide nanowires in a solution containing titanium oxysulfate and urea, thereby forming titanium dioxide fine particles on the surface of said titanium dioxide nanowires; and
recovering said titanium dioxide nanowires having said titanium dioxide fine particles formed on the surface thereof.

2. The method for production of a titanium dioxide composite as defined in claim 1, wherein said titanium dioxide nanowires have a diameter no smaller than 50 nm and no larger than 110 nm.

3. The method for production of a titanium dioxide composite as defined in claim 1, wherein said titanium dioxide fine particles have a diameter no smaller than 5 nm and no larger than 150 nm.

4. The method for production of a titanium dioxide composite as defined in claim 1, wherein said titanium dioxide nanowires are single-crystal nanowires of anatase type.

5. The method for production of a titanium dioxide composite as defined in claim 1, wherein said titanium dioxide fine particles are those of anatase type.

6. A titanium dioxide composite which comprises titanium dioxide nanowires and titanium dioxide fine particles formed on the surface thereof, wherein said titanium dioxide nanowires have a diameter no smaller than 50 nm and no larger than 110 nm.

7. The titanium dioxide composite as defined in claim 6, wherein said titanium dioxide fine particles have a diameter no smaller than 5 nm and no larger than 150 nm.

8. A photoelectric conversion device which comprises:
a working electrode provided with a semiconductor layer formed from a titanium dioxide composite which comprises titanium dioxide nanowires and titanium dioxide fine particles formed on the surface thereof, wherein said titanium dioxide nanowires have a diameter no smaller than 50 nm and no larger than 110 nm;
a counter electrode arranged opposite to said working electrode; and
an electrolyte layer interposed between said working electrode and said counter electrode,
with said titanium dioxide composite having a dye supported on the surface of said titanium dioxide nanowires and said titanium dioxide fine particles.
